(19) United States
(12) Patent Application Publication
(10) Pub. No.: US 2013/0294161 A1
(43) Pub. Date: Nov. 7, 2013

(54) LOW-VOLTAGE FAST-WRITE NVSRAM CELL

(71) Applicants: Peter Wung Lee, Saratoga, CA (US); Hsing-Ya Tsao, San Jose, CA (US)

(72) Inventors: Peter Wung Lee, Saratoga, CA (US); Hsing-Ya Tsao, San Jose, CA (US)

(73) Assignee: APlus Flash Technology, Inc., San Jose, CA (US)

(21) Appl. No.: 13/888,134

(22) Filed: May 6, 2013

Related U.S. Application Data
(60) Provisional application No. 61/688,107, filed on May 7, 2012.

(51) Int. Cl. G11C 16/04

(52) U.S. Cl. CPC G11C 16/0433; G11C 16/0466
USPC 365/185.08; 365/154

(57) ABSTRACT

This invention discloses several embodiments of a low-voltage fast-write NVSRAM cells, made of either of a 2-poly floating-gate type flash cell or a 1-poly charge-trapping SONOS or MONOS flash cell with improvement by adding a Bridge circuit. This Bridge circuit is preferably inserted between each LV 6T SRAM cell and each HV Flash cell that comprises one paired complementary Flash strings. The Flash strings can be made of either 2T or 3T Flash strings. The tradeoff of using either a 2T or a 3T Flash string is subject to the gate area penalty and required design specs. One improvement for adding the Bridge circuit into the NVSRAM cell is to ensure the data writing between Flash cell and SRAM cell with the same polarity and to allow the operation down to low 1.2V Vdd.

### CROSS-REFERENCES TO RELATED APPLICATIONS

This application claims priority to U.S. Provisional Patent Application No. 61/688,107, filed on May 7, 2012, commonly assigned, and hereby incorporated by reference in its entirety herein for all purposes.

This application is related to U.S. Pat. Nos. 8,018,768, 7,760,540, 7,110,293, and 7,859,899.

### BACKGROUND OF THE INVENTION

The present invention is generally related with a novel design of static random-access memory (SRAM)-based non-volatile random-access memory (NVRAM) cell structure and array for an extremely fast write (program and erase) speed but low write and read voltage, for an extremely high-density, in-circuit or in-system programmable and erasable field-programmable gate array (FPGA) and NVRAM designs.

The LV SRAM-based FPGA is well known in the art. It is leading in the FPGA market place over today's HV Flash-based FPGA design. The LV SRAM-based FPGA cell and design achieves the highest cell's scalability down to 2×nm in 2012, while the most advanced HV Flash-based FPGA cell and technology node is only at 65 nm.

But there are several severe drawbacks of the today's SRAM-based FPGA cell and its associated designs when memory density requirement is getting higher and higher up to 1 Gb for those very sophisticated configurable logic design. These drawbacks include the followings:
a) Lengthy time consuming and high power consumption to write the huge data from off-chip Flash memory into on-chip distributed SRAM memory clusters during Vdd power-up cycle of prior-art FPGA chip.
b) No effective solution to immediately back up the on-chip volatile SRAMs' huge data into on-chip non-volatile Flash memory upon a sudden Vdd power loss without a costly support of off-chip battery-backup system.
c) The high security risk of losing off-chip stored configuration bit information by the intended hackers.
   As a result, there are strong needs in the FPGA market to have a novel volatile SRAM-based FPGA design with on-chip non-volatile Flash storage capability for higher security, less power-consumption and faster write speed at low 1.2V Vdd operating voltage.

Currently, the mainstream FPGA designs in 2012 are being divided into two groups with two distinct technologies. The first group is the LV SRAM-based FPGA design which leads the market. These LV SRAM-based FPGA companies include Altera, Xilink and many other smaller players. The second group is the HV NVM-based FPGA design, which grabs much smaller market revenues. These NVM-based FPGA companies include Actel, Lattice and the smaller part of Altera.

Some other approaches different from above two distinct designs may have both LV SRAM cells and HV Flash cells on 1-die, they also have other drawbacks. For example, the on-chip Flash memory is used to store the total configuration bits in one or few central memory array areas. During the Vdd power-up, the stored configuration bits on on-chip Flash memory needs to be down complicatedly loaded into the on-chip distributed SRAM cells sequentially with huge time and power consuming. The on-chip state-machine design becomes very difficult and challenging.

The worst-case concern is that when a sudden unexpected Vdd power loss, the huge on-chip SRAM data bits of 200 Mb cannot be safely written into the on-chip huge Flash memory within a period as short as 10 ms by the sudden power-loss without a costly battery back-up. Although there are many Flash memories available in 2012, most of them have different kinds of drawbacks and are not suitable for the SRAM-based NVRAM cell design to directly meet the above said design requirements without the modifications.

Therefore, an improved SRAM-based NVRAM cell design and their associated operations are needed and become objectives of the present invention.

### BRIEF SUMMARY OF THE INVENTION

The present invention is generally related with a novel design of static random-access memory (SRAM)-based non-volatile random-access memory (NVRAM) cell structure and array for an extremely fast write (Program and Erase) speed but low Write and Read voltage, for an extremely high-density, in-circuit or in-system programmable and erasable field-programmable gate array (FPGA) and NVRAM designs.

The objectives for this invention of novel NVSRAM cell and its associated controls can be divided into two groups. One group's objective is for traditional FPGA, the other group's objective is for the traditional NVRAM applications. But the goal is to use one NVSRAM cell for both FPGA and NVRAM applications, thus there are some common objectives for both applications. From our study, the preferred Flash cell structures and their associated operations have to meet the following specs:
a) Both program and erase schemes have to be the well-know production proven low-current FN-channel tunneling (10PA per cell) like NAND cell: Those using high-current CHE-program NOR Flash cells cannot be used. These NOR companies include Numonyx's 2-poly floating-gate cell and Spansion's 1-poly charge-trapping SONOS cell. Although the traditional 2T Flotox-based EEPROM cell using the same low-current FN scheme for both Program and Erase operations, the cell size is too big. Furthermore, SST's super-Flash cell cannot be used here due to its high 1 μA program current.
b) The Flash's Program and Program-Inhibit channel voltages of each selected paired Flash strings require only Vss and Vdd from each corresponding SRAM's BL and BLB when self-boosting WL program scheme is adopted in today's NAND. But for successfully operating down to 1.2V Vdd, the WL's Program voltage of 20V in NAND design is too high to reach during the power-down short period. As a result, the increase of Flash cell's coupling ratio is desired to reduce the WL voltage down below 12V.

An objective of this invention is to provide a novel 16T SRAM-based NVSRAM cell structure that comprises 1-bit of 6T-SRAM-based FPGA cell along with 1-bit of a paired Flash strings stored with two complementary Vₜs. Each Flash string consists of three transistors (3T) with one 2-poly floating-gate flash cell or 1-poly SONOS charge-trapping flash cell and two other 1-poly NMOS devices.

Another objective of this invention is to provide a novel method to increase the Flash cell's word line (WL) coupling ratio of the NVSRAM cell so that Flash cells can be erased and programmed with low-current FN-tunneling scheme at lower WL voltage with respect to 0V set in Flash cell's channel. As a result, the on-chip charge-pump size, power consumption, and write time can be drastically reduced when the NVSRAM cell is operating at 1.2V Vdd.

Further, another object of this invention is to make the equivalent pull-down resistance of each long Flash string lower than the PMOS pull-up resistance of each corresponding SRAM cell with sufficient margin to allow the quick and safe data loading from each Flash cell into each SRAM cell of each NVSRAM cell, operating at low 1.2V Vdd.

Even further, another object of this invention is to gate each paired inputs of each Flash cell input to both Q and QB data nodes of each SRAM cell of each NVSRAM cell so that the data writing from each SRAM loads into each Flash cell via one direct route and the data loads from each Flash cell into each SRAM cell through an opposite route. As a result, the reversed polarity of each Flash cell's writing data can be reversely loaded into each corresponding SRAM cell for correct data reading.

Yet another objective of this invention is to provide one preferred set of Erase bias conditions to allow −12V or lower Flash cell's negative WL voltage to achieve the successful FN-channel tunneling effect on each 2-poly Flash cell of each NVSRAM cell.

Still yet another objective of this invention is to provide another preferred set of Erase bias conditions with enhancing FN-tunneling electrical field so that the required erase time for each 2-poly floating-gate Flash cell of each NVSRAM cell can be shortened.

An alternative objective of this invention is to provide one preferred set of Program bias conditions to allow +12V or lower Flash cell's positive WL voltage to achieve the successful FN-channel tunneling effect on each 2-poly floating-gate Flash cell of each NVSRAM cell.

Another alternative objective of this invention is to provide similar preferred set of Erase bias conditions to allow −7V or even lower Flash cell's negative WL voltage to achieve the successful FN-channel tunneling effect on each 1-poly charge-trapping SONOS-type Flash cell of each NVSRAM cell.

Yet another alternative objective of this invention is to provide similar preferred set of Program bias conditions to allow +7V or lower Flash cell's positive WL voltage to achieve the successful FN-channel tunneling effect on each 1-poly charge-trapping SONOS-type Flash cell of each NVSRAM cell.

Still another alternative objective of this invention is to provide a preferred timeline to show how to correctly program each SRAM data into each Flash cell of each NVSRAM cell.

The Flash cell includes both 2-poly floating-gate Flash cell and 1-poly charge-trapping SONOS-type Flash cell.

Yet still another alternative objective of this invention is to provide a preferred timeline to show how to correctly load each Flash cell's data into each corresponding SRAM cell of each NVSRAM cell. The Flash cell includes both 2-poly floating-gate Flash cell and 1-poly charge-trapping SONOS-type Flash cell.

Yet additional alternative objective of this invention is to provide a preferred timeline to show how to correctly erase each Flash cell of each NVSRAM cell. The Flash cell includes both 2-poly floating-gate Flash cell and 1-poly charge-trapping SONOS-type Flash cell.

Still additional alternative objective of this invention is to provide a preferred timeline to show how to correctly read each SRAM cell out from each NVSRAM cell with Flash cells equivalently out of circuit, irrespective of 2-poly floating-gate Flash cell or 1-poly charge-trapping SONOS-type Flash cell.

In a specific embodiment, the present invention provides a 16T NVSRAM memory cell circuit with low-voltage fast-write scheme. The NVSRAM memory cell includes a SRAM cell comprising a first access transistor and a second access transistor sharing a first word line and respectively coupling between a first bit line and a first data node and between a second bit line and a second data node. The first data node and the second data node respectively are coupled to two cross-coupled invertors made by four LV CMOS transistors. Additionally, the NVSRAM memory cell includes a Flash cell comprising a first cell string and a second cell string sharing a common P-sub. The first/second cell string includes a first/second top Select transistor, a first/second Flash transistor, and a first/second bottom Select transistor connected in series. The first and the second top Select transistors are gated commonly by a first select-gate control line and respectively associated with a first drain terminal and a second drain terminal. The first and the second bottom Select transistors are gated commonly by a second select-gate control line and respectively associated with a first source terminal and a second source terminal. The first and the second Flash transistors are gated commonly by a second word line and the first source terminal and the second source terminal are connected together to a flash source line. Moreover, the NVSRAM memory cell includes a Bridge circuit including a first, second, third, and fourth LV NMOS transistor for connecting the first data node and the second data node of the SRAM cell respectively through two cross routes to the first drain terminal and the second drain terminal of the Flash cell. The first and the third LV NMOS transistors are commonly gated by a FSwrite control line and the second and the fourth LV NMOS transistors are commonly gated by a SFwrite control line. The first and the second LV NMOS transistors have a first common drain node connected to the first data node of the SRAM cell. The second and the third LV NMOS transistors have a first common source node connected to the first drain terminal of the Flash cell. The third and the fourth LV NMOS transistors have a second common drain node connected to the second data node of the SRAM cell. The first and the fourth LV NMOS transistors have a second common source node connected to the second drain terminal of the Flash cell. In an embodiment, only one of the FSwrite control line and the SFwrite control line is turned on at a time by coupling to a power supply voltage as low as 1.2 V Vdd for providing a direct route of writing data from the SRAM cell to the Flash cell via a FN tunneling effect by setting only one HV of +12V or lower the second word line and providing an alternate route of loading data from the Flash cell to the SRAM cell by conducting current from the first or second data node to a grounded flash source line so that a reversed polarity of each data from the Flash cell can be reversely loaded into the SRAM cell operating at the power supply voltage as low as 1.2 V Vdd.

In an alternative embodiment, the present invention provides a 14T NVSRAM memory cell circuit with low-voltage fast-write scheme. The NVSRAM memory cell includes a SRAM cell comprising a first access transistor and a second access transistor sharing a first word line and respectively coupling between a first bit line and a first data node and between a second bit line and a second data node. The first data node and the second data node respectively are coupled to two cross-coupled invertors made by four LV CMOS transistors. Additionally, the NVSRAM memory cell includes a Flash cell comprising a first cell string and a second cell string sharing a common P-sub. The first/second cell string includes at least a first/second Flash transistor connected in series to a first/second Select transistor. The first and the second Select transistors are gated commonly by a select-gate control line and respectively associated with a first source terminal and a second source terminal. The first and the second Flash transistors are gated commonly by a second word line. The first source terminal and the second source terminal are connected together to a flash source line. Furthermore, the NVSRAM memory cell includes a Bridge circuit including a first, second, third, and fourth HV NMOS transistor for connecting the first data node and the second data node of the SRAM cell respectively through two cross routes to the first drain terminal and the second drain terminal of the Flash cell. The first and the third HV NMOS transistors are commonly gated by a FSwrite control line and the second and the fourth HV NMOS transistors are commonly gated by a SFwrite control line. The first and the second HV NMOS transistors have a first common drain node connected to the first data node of the SRAM cell. The second and the third HV NMOS transistors have a first common source node connected to the first drain terminal of the Flash cell. The third and the fourth HV NMOS transistors have a second common drain node connected to the second data node of the SRAM cell. The first and the fourth HV NMOS transistors have a second common source node connected to the second drain terminal of the Flash cell. In a specific embodiment, only one of the FSwrite control line and the SFwrite control line is turned on at a time by coupling to a power supply voltage as low as 1.2 V Vdd for providing a direct route of writing data from the SRAM cell to the Flash cell via a FN tunneling effect by setting only one HV of +12V or lower the second word line and providing an alternate route of loading data from the Flash cell to the SRAM cell by conducting current from the first or second data node to a grounded flash source line so that a reversed polarity of each data from the Flash cell can be reversely loaded into the SRAM cell operating at the power supply voltage as low as 1.2V Vdd.

More specifically, this invention is to provide a novel new SRAM-based NVRAM cell structure which is preferably comprised of one regular 6T SRAM CMOS cell and one pair of 4T Flash strings. Although the total number of transistors (T) of the present invention is 14, which may be larger than most of similar prior art, the NVRAM cell structure and biased conditions and array operations have been much simplified to achieve the lower write voltage but faster write speed from the volatile SRAM cell into non-volatile Flash during the normal or unexpected power down mode or from non-volatile Flash data into volatile SRAM cell during normal Vdd power-up, collectively and simultaneously for whole extremely high-density FPGA array with density up to 1 Gb.

During the normal read operation of the 16T (or 14T) NVRAM cell of the present invention, one pair of 3T (or 2T) Flash strings are totally isolated from 6T SRAM cell from electrical circuit point of view. As a result, the preferred Read operation is like the SRAM-based FPGA so that the performance of FPGA is not degraded.

During the write operation from each SRAM cell on Flash pairs in regular or undesired power-off situations, each of one-pair outputs of the SRAM cell provides a paired LV Program (Vss) voltage and Program-Inhibit (Vdd) voltage so that the NVRAM's Flash pairs can be quickly and correctly programmed without reversing the data polarity at 1.2V Vdd operation.

Many benefits can be achieved by applying the embodiments of the present invention. These and other benefits may be described throughout the present specification and more particularly below.

### BRIEF DESCRIPTION OF THE DRAWINGS

FIG. 1a is a schematic diagram of a 3T Flash string used in a NVSRAM cell of prior art.

FIG. 1b is a cross-sectional diagram of above 3T Flash string circuit used in a NVSRAM cell of prior art.

FIG. 1c is a schematic diagram of a NVSRAM cell of prior art.

FIG. 1d is a table that provides a set of bias conditions for various key NVSRAM operations such as Erase and Program and Program-Inhibit of the Flash cell and Read of the SRAM cell of the NVSAM cell of prior art.

FIG. 2a is another schematic diagram of a 3T Flash string used in another NVSRAM cell of prior art.

FIG. 2b is a similar cross-sectional diagram of above 3T 1-poly charge-trapping type Flash string circuit used in a NVSRAM cell of prior art of FIG. 2a.

FIG. 2c is a schematic diagram of another NVSRAM cell of prior art.

FIG. 2d is a table that provides another set of bias conditions for various key NVSRAM operations of FIG. 2c.

FIG. 3a is a schematic diagram of a 16T 2-poly NVSRAM cell according to an embodiment of the present invention.

FIG. 3b is a table that provides a preferred set of bias conditions for various key NVSRAM operations according to an embodiment of the present invention.

FIG. 3c is a timeline for operating the 3T Flash string of the 16T 2-poly NVSRAM cell according to an embodiment of the present invention.

FIG. 4a is a schematic diagram of a 14T 2-poly NVSRAM cell according to another embodiment of the present invention.

FIG. 4b is a table that provides a preferred set of bias conditions for various key 2-poly NVSRAM operations according to an embodiment of the present invention.

FIG. 4c is another timeline for operating the 2T Flash string of the 14T 2-poly NVSRAM cell according to another embodiment of the present invention.

FIG. 5 is a schematic diagram of a 16T 1-poly NVSRAM cell with one pair of 3T Flash strings according to an embodiment of the present invention.

FIG. 6 is a schematic diagram of a 14T 1-poly NVSRAM cell with one pair of 2T Flash strings according to another embodiment of the present invention.

### DETAILED DESCRIPTION OF THE INVENTION

The present invention is generally related with a novel design of static random-access memory (SRAM)-based non-volatile random-access memory (NVRAM) cell structure and array for an extremely fast write (program and erase) speed but low write and read voltage, for an extremely high-density, in-circuit or in-system programmable and erasable field-programmable gate array (FPGA) and NVRAM designs. More particularly, embodiments of the present invention provide a NVSRAM cell structure that is tailored for those SRAM-based FPGA IC designs with a stringent requirement of extremely high memory density of up to 1 Gb, a read operation with low-power Vdd down to 1.2V but with an extremely fast in-system repeatedly configurable speed of 10 ms.

More specifically, this invention is to provide a novel new SRAM-based NVRAM cell structure which is preferably comprised of one regular 6T SRAM CMOS cell and one pair of 4T Flash cell. Although the total number of transistors (T) of the present invention is 14, which may be larger than most of similar prior art, the NVAM cell structure and biased conditions and array operations have been much simplified to achieve the lower write voltage but faster write speed from the volatile SRAM cell into non-volatile Flash during the normal or unexpected power down mode or from non-volatile Flash data into volatile SRAM cell during normal Vdd power-up, collectively and simultaneously for whole extremely high-density FPGA array with density up to 1 Gb.

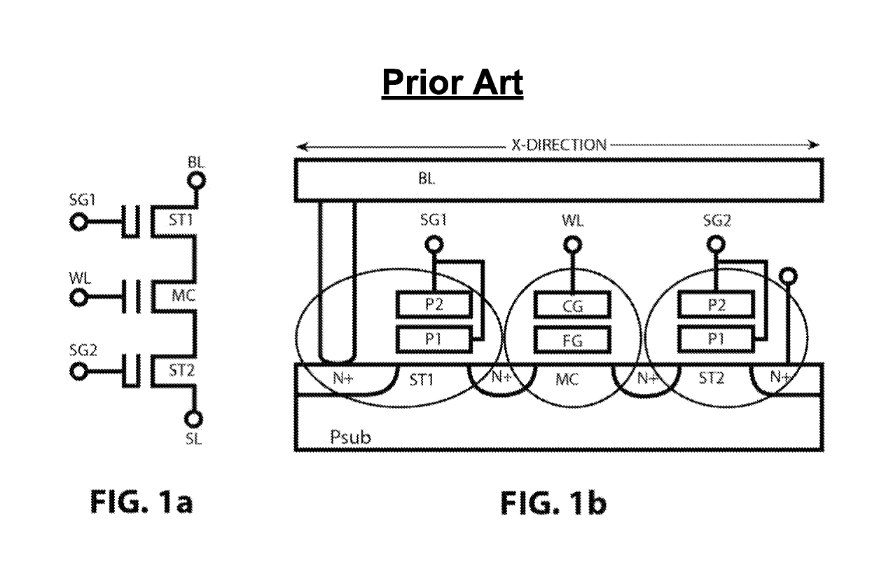

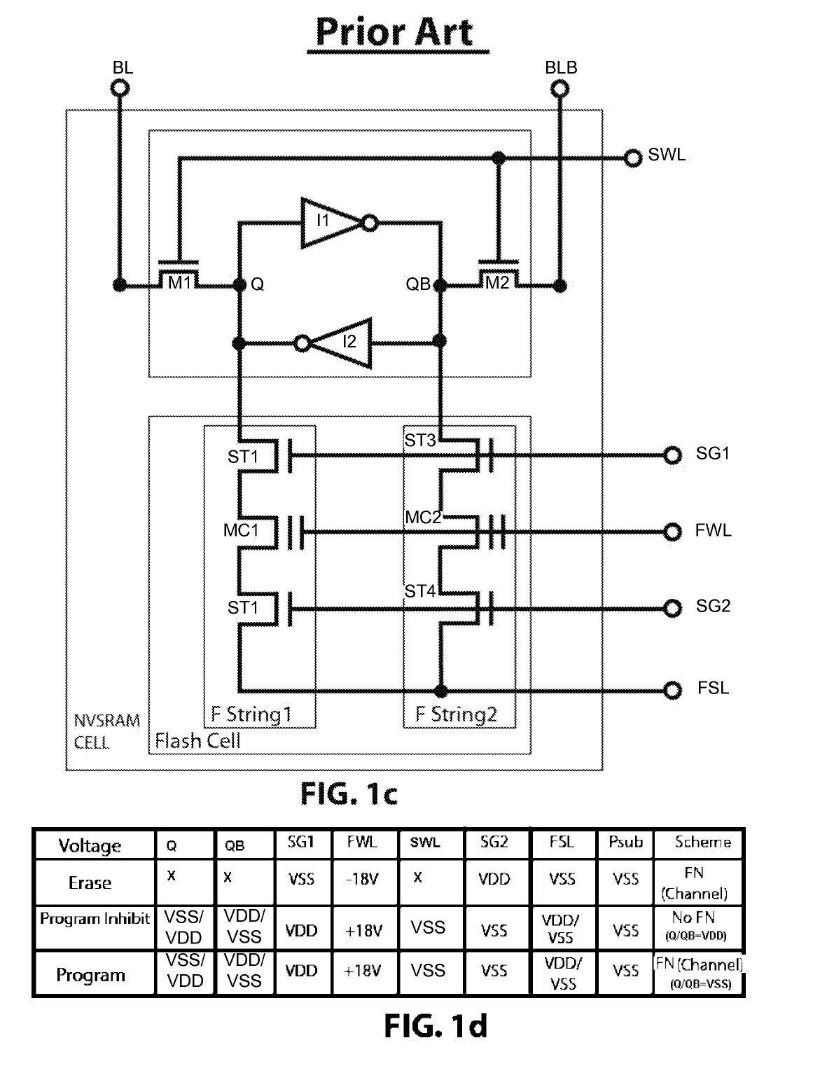

FIG. 1a is a schematic diagram of a 3T Flash string used in a NVSRAM cell of prior art. Presenting this traditional NVSRAM cell diagram is merely used as part of an inventive process as described below. As seen, a Flash string consists of two 1-poly HV NMOS Select transistors, ST1 and ST2, and one 2-poly floating-gate type NMOS Flash transistor, MC. The 1-poly Select transistor is formed by shorting Poly2 control-gate to Poly1 floating-gate. The three transistors of each Flash string are connected in series from the drain node of BL to the source node of SL. The channel widths of the three transistors are either made the same or different, depending on the applications and design specs.

There are well-known pros and cons for the 3T Flash string structure as summarized below.

1) Cons:
a) The effective cell size is increased in layout:
If the 3T Flash string structure is used to replace the 1T flash cell, each Flash part of each NVSRAM cell takes more area due to increase of the transistor numbers from 1 to 3.
b) The 3T Flash string's equivalent resistance is increased, thus sensing current is reduced:
It is due to adding resistance from the top and bottom 1-poly Select NMOS transistors, ST1 and ST2, connected in series with the flash cell, MC, placed in the middle. Typically, the 3T Flash string current is smaller than the 1T flash cell by 30% if all transistors are made with same channel width.

2) Pros:
a) Only the low-voltage Vdd Program-Inhibit voltage and the Vss Program voltage are required during Flash FN-channel Program operation:
The 3T Flash string adopts the common Self-Boosting Program Inhibit (SBPI) scheme that just needs Vdd to be coupled to the top terminal used extensively in NAND but with a much long cell string. When Vss is coupled to the top terminal of the 3T Flash string, the selected flash cell would be programmed to achieve higher Vₜ of more than 2.0V after the predetermined program cycle of 1 ms.
b) The SBPI-induced HV of 7V in channel of each flash cell is isolated from SRAM's paired LV outputs of Q and QB nodes due to the protection of two top Select transistors ST1 and ST3. As a result, the SRAM cell would not be damaged during Flash string's HV Program operation. The two bottom Select transistors ST2 and ST4 are shut off to avoid channel leakage to ensure the proper operation within the SBPI method. All Select transistors of ST1, ST2, ST3 and ST4 have to be HV device to sustain the channel punch-through voltage Vds of about 7V when SBPI operation happens in the flash channel that could spread to the source nodes of ST1 and ST3 and drains nodes of ST2 and ST4. In order to make a compact Flash string to ensure the success of SBPI operation, the ST1, ST2, ST3, ST4 and MC1 and MC2 are preferably made within the same P-sub or Triple P-well to reduce the junction capacitance between MC and ST transistors in the same string.

FIG. 1b is a cross-sectional diagram of above 3T Flash string circuit used in a NVSRAM cell of prior art. Presenting this traditional NVSRAM cell diagram is merely used as part of an inventive process as described below. As seen, the two 1-poly HV NMOS Select transistors, ST1 and ST2, and one 2-poly floating-gate type NMOS transistor are all formed on the common P-sub. The top terminal of the Flash string is connected to BL (Metal bit line) and the bottom terminal is connected to SL (source line). The drawing has indicated ST1 and ST2 transistors' Poly2 and Poly1 gate being shorted to form a Poly1-gate NMOS device.

During the SBPI programming scheme, the channel of 2-poly flash transistor's voltage can be boosted up with HV value, ranging from 7V to 10V when flash gate voltage, FWL, is ramped to +18V. The electrical field between flash channel and Poly2 gate voltage, FWL, is then reduced to 11V. As a result, the electrical filed between the float-gate and channel is drastically reduced to below 3V providing the coupling ratio from flash control-gate to the floating-gate is around 70%. Thus the FN channel tunneling effect would not happen to the Program-Inhibited flash cell in one of the non-selected Flash string of each NVSRAM cell.

Conversely, the selected flash cell with its channel is held at Vss when its WL-gate is ramped to +18V during the program operation. The effective tunnel oxide electrical filed would exceed 10 mV/cm to induce the desired FN-channel tunneling effect. As a result, the selected flash cell's Vₜ would be increased above 2V in one of the selected Flash string of the selected NVSRAM cell after the Program operation.

FIG. 1c is a schematic diagram of a NVSRAM cell of prior art. It comprises a 6T CMOS SRAM cell on top and a Flash cell on bottom comprising of two 3T Flash strings as shown in FIG. 1b. The Flash type is 2-poly floating-gate NMOS cell. Again, presenting this traditional NVSRAM cell diagram is merely used as part of an inventive process as described below. Dung a SRAM normal operation, SG1 is coupled to Vss to completely isolate two Flash strings of each Flash cell from each SRAM cell. As a result, the SRAM's read and write operations would not be disturbed and each Flash cell is transparent to each SRAM cell of each NVSRAM cell of prior art.

During each data writing from each 6T-SRAM cell into two Flash strings of each corresponding Flash cell, the word line of the SRAM cell (SWL) is grounded to isolate SRAM's latch from the global BL and BLB lines. That means the data writing is only performed exclusively between each 6T SRAM cell and each Flash cell in a local area.

The data writing from 1-bit 6T-SRAM into Flash is performed on two complementary flash bits (cells), MC1 and MC2, of two 3T Flash strings respectively denoted as FString 1 and FString2. In normal program operation, only one bit of MC1 and MC2 get programmed and one bit gets program-inhibited.

FIG. 1d is a table that provides a set of bias conditions for various key NVSRAM operations such as Erase and Program and Program-Inhibit of the Flash cell and Read of the SRAM cell of the NVSAM cell of prior art. Presenting these traditional NVSRAM operations is merely used as part of an inventive process as described below. Since this NVSRAM has 2-poly Flash string, thus the disadvantage of Erase and Program operating lies in the need to use much higher FWL voltages of −18V and +18V respectively.

The Vₜ level of the programmed flash cell would be Vₜ1 and is designed to be ≧+2V, while the Vₜ level of the inhibited flash cell would stay unchanged as the initial erased Vₜ level before program. The erased Vₜ level is Vₜ0 and is typically set to be ≦−2V. Therefore, in the beginning of Flash write operation, a FN-channel erase operation is performed prior to the FN-channel Program operation. After FN-channel Erase operation, both flash cells' Vₜs are erased to be identical with a targeted value ≦−2V. But after FN channel Program operation, one bit of the selected flash cell's Vₜ level would be increased to Vₜ1 of a value ≧2V. As a result, after FN program, the paired flash cells in the paired Flash strings would store two complementary Vₜs such as +2V of Vₜ1 and −2V of Vₜ0.

For example, if the SRAM's Q and QB data node are set to be Vdd and Vss, then the Vₜ level associated with the flash transistor MC1 would stay with Vₜ0 of −2V, while the Vₜ level associated with the flash transistor MC2 would be changed to Vₜ1 of +2V. As shown, the paired stored data of MC1 and MC2 are opposite of the stored data of paired Q and QB of each SRAM cell after FN channel Program. That would lead to wrongly loading Flash reverse data into each SRAM during the power up cycle if it is not handled correctly. Even worse is when the 1.2V Vdd operation is applied to the NVSRAM cell, correct loading of Flash data into SRAM cell will fail.

It is because the correct data loading from Flash cell to SRAM cell requires a high voltage value of Vdd−Vₜ(max) to set the SRAM cell into right state, where Vₜ(max) level is defined by the largest Vₜ value of transistors in each FString. Typically, the Vₜ levels of Select transistors ST1 and ST2 are the same with a value around 0.7V. But the Vₜ levels of the flash transistors MC1 and MC2 are set with complementary values of Vₜ1=+2V and Vₜ0=−2V. Therefore, the equivalent Vₜ(max) level of each FString is determined by the Select transistors ST's Vₜ level of 0.7V provided that the flash transistor MC's Vₜ level is at Vₜ0. By the contrast, the equivalent Vₜ(max) level of each FString is determined by the stored Vₜ1 of 2V associated with the flash transistor MC. When Vdd is 1.8V or higher, a current flow from FSL to charge either Q or QB node of the 6T-SRAM up to Vdd−Vₜ(max) to set the SRAM cell. If Q node is being charged up, then the Q voltage is set to be Vdd and QB is Vss. If the QB is being charged up, then QB voltage is Vdd but Q is Vss.

But when the operation of 1.2V Vdd operation is implemented for the NVSRAM, Vdd-Vₜ(max) becomes only 0.5V in the worst-case condition mentioned above, from which it is not high enough than Vₜ level of NMOS transistors of two invertors I1 and I2. As a result, the data loading from the Flash cell into the corresponding SRAM cell of each NVSRAM cell would fail at such the low 1.2V Vdd operation. Thus, using charge-up approach from FSL to Q or QB node of SRAM at the 1.2V Vdd operation is no longer valid. An improvement over the NMOS-type NVSRAM cell for 1.2V Vdd operation is needed.

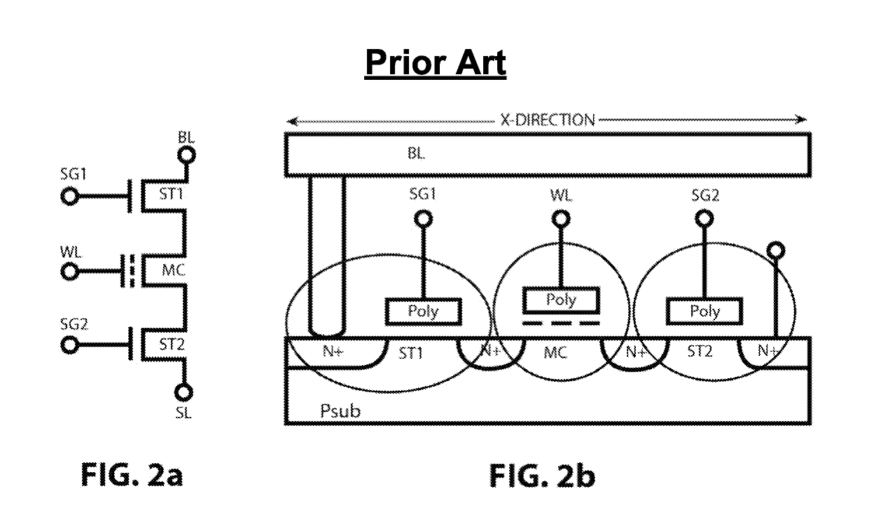

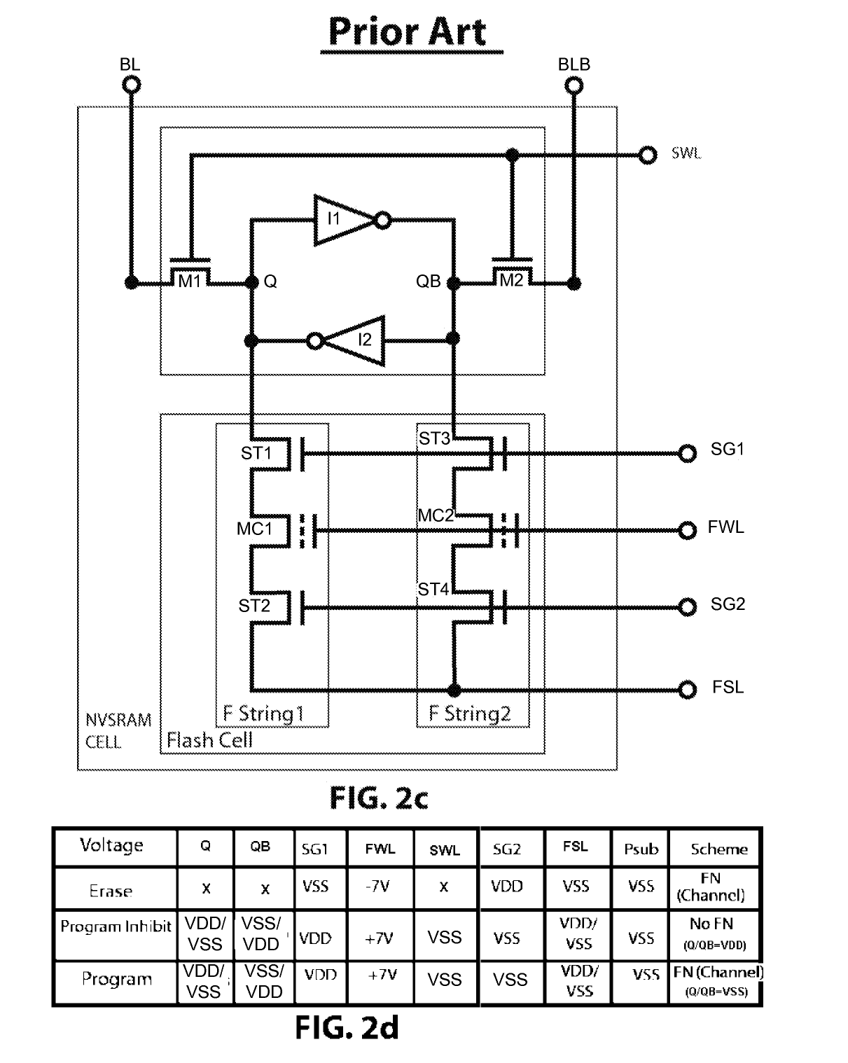

FIG. 2a is another schematic diagram of a 3T Flash string used in another NVSRAM cell of prior art. Further, presenting this traditional NVSRAM cell diagram is merely used as part of an inventive process as described below. Similarly, the Flash string consists of two 1-poly HV NMOS Select transistors, ST1 and ST2, and one 1-poly but charge-trapping type, SONOS or MONOS, NMOS flash transistor, MC, unlike the Poly1-gate transistor of ST1 and ST2 shown in FIG. 1a, which is formed by shorting poly2 and poly1. The ST1 and ST2 transistors of the FIG. 2a are the regular single poly-gate NMOS devices because this prior art uses single-poly process. The flash cell, MC, is a single-poly charge-trapping SONOS or MONOS Flash storage transistor.

FIG. 2b shows a cross-sectional diagram of above 3T 1-poly charge-trapping type Flash string circuit used in a NVSRAM cell of prior art shown in FIG. 2a. The two regular HV NMOS Select transistors, ST1 and ST2, and one 1-poly charge-trapping-gate type NMOS flash transistor are all formed on the common P-sub. Similarly, the top terminal of each Flash string is connected to BL (Metal bit line) and the bottom terminal is also connected to SL (source line). Another complementary Flash string of the same Flash cell, its top terminal is connected to QB node of same 6T SRAM but the SL is shared by the paired Flash strings.

FIG. 2c shows a similar schematic diagram of another NVSRAM cell of prior art. It also comprises a 6T CMOS SRAM cell on top and a Flash cell on bottom comprising of two 3T Flash strings as shown in FIG. 2b. The Flash cell type is the single-poly charge-trapping SONOS or MONOS transistor.

FIG. 2d shows a table that provides another set of bias conditions for various key operations of the NVSRAM cell of FIG. 2c. These operations include Erase, Program and Program Inhibit of the Flash cell of the SRAM cell of the 1-poly NVSRAM cell. Since this NVSRAM cell comprises two single-poly Flash strings, an advantage is that for Erase and Program operations of the NVSRAM cell the word line of the Flash cell (FWL) uses much lower gate voltages of +7V and −7V than the ones used in the 2-poly flash transistor as shown in FIG. 1c.

However, when the 1.2V Vdd operation is implemented in the NVSRAM cell, the similar charge-up voltage of Vdd−Vₜ(max) becomes only 0.5V in the worst-case condition as mentioned above. The charge-up voltage Vdd−Vₜ(max) is not high enough to surpass the threshold voltage Vₜ level of NMOS transistor of the two invertors I1 and I2. As a result, the similar data loading from the two flash transistors, MC1 and MC2, into the corresponding data nodes of the SRAM cell of each NVSRAM cell would fail in such a low 1.2V Vdd operation. Thus, using the similar charge-up approach from a source line of the Flash cell (FSL) to either Q or QB data node of SRAM cell at 1.2V Vdd operation is no longer valid for this SONOS-type NVSRAM cell. An improvement for the SONOS-type NVSRAM cell in 1.2V Vdd operation is needed.

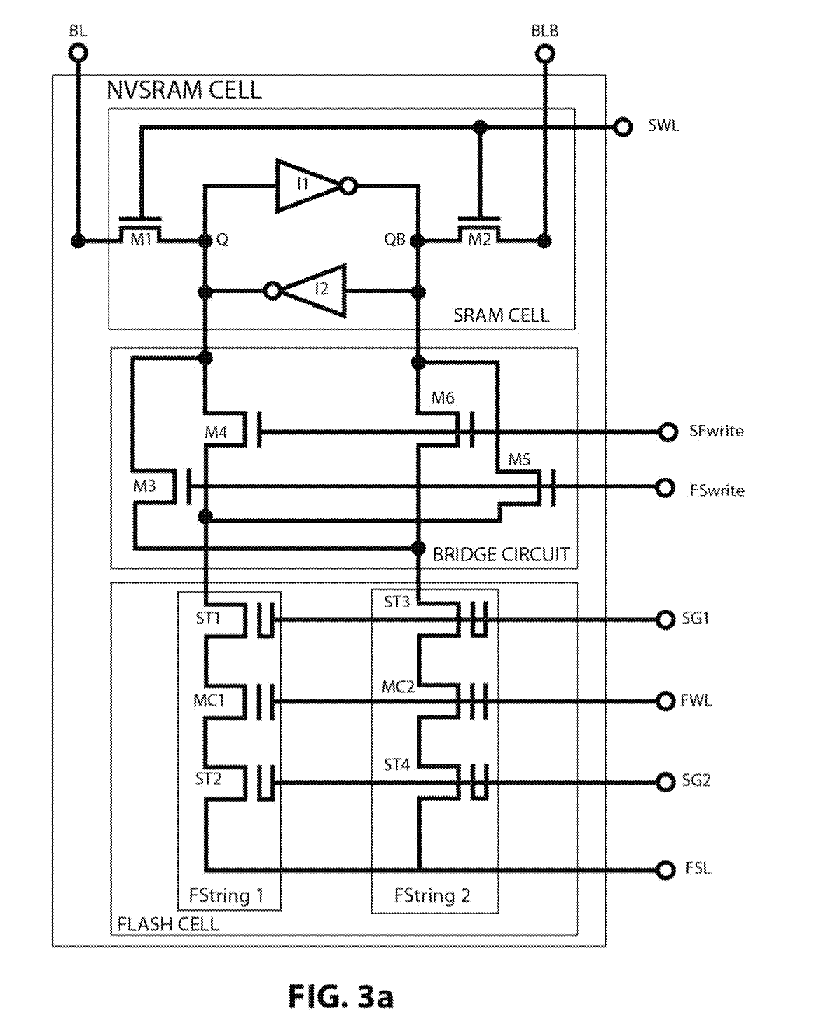

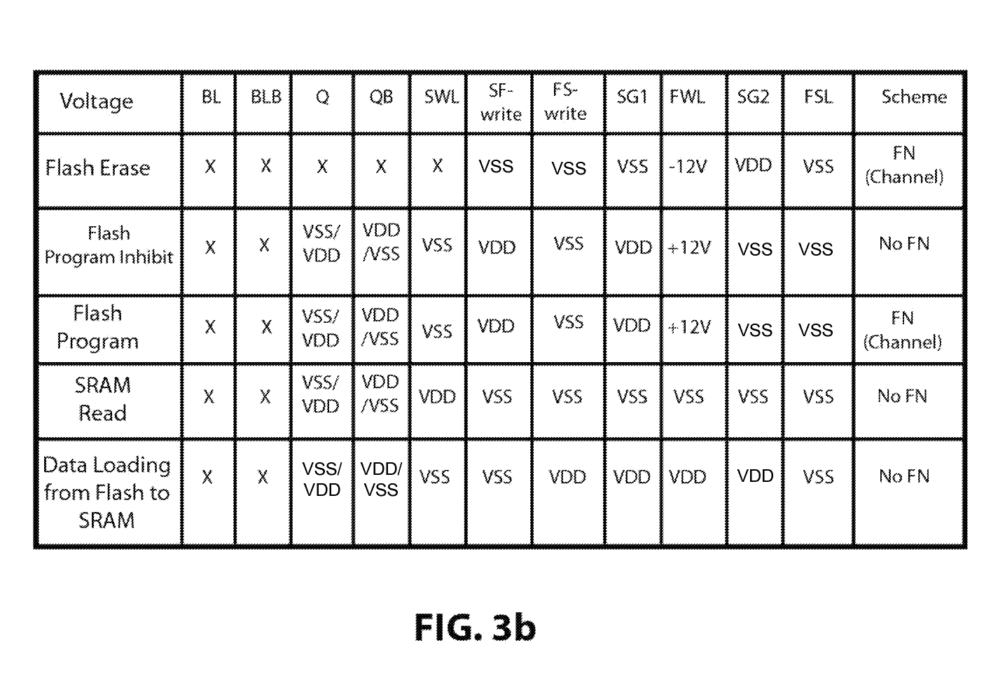

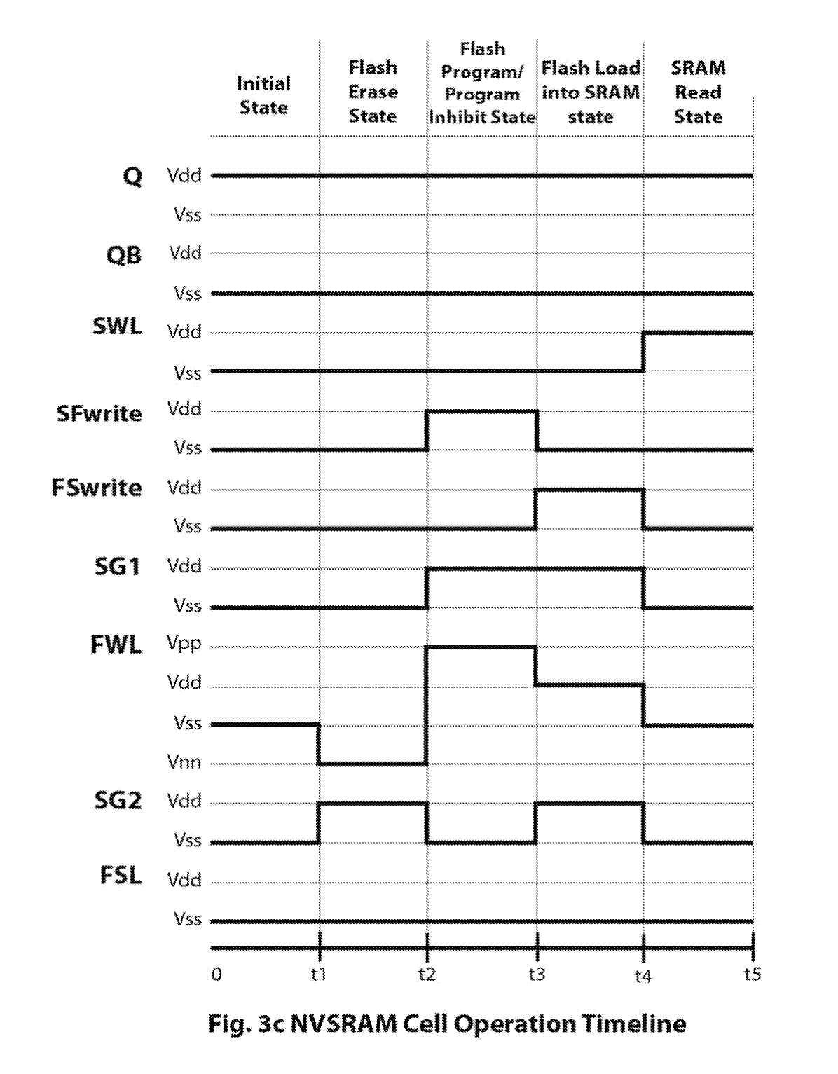

FIG. 3a is a schematic diagram of a 16T 2-poly NVSRAM cell according to an embodiment of the present invention. This diagram is merely an example, which should not unduly limit the scope of the claims herein. One of ordinary skill in the art would recognize other variations, modifications, and alternatives. As shown, unlike the previous 2-poly NVSRAM cell shown in FIG. 1c, in addition to a 6T SRAM cell and a Flash cell with two 3T strings, each new NVSRAM cell of this invention has one Bridge-circuit inserted between each SRAM cell and each Flash cell.

Each Bridge circuit comprises four LV NMOS devices such as M3 and M5 with their common gate tied to FSwrite and M4 and M6 with their gates tied to SFwrite separately. These four LV 1-poly NMOS devices can be made exactly the same oxide-thickness of SRAM's NMOS devices in Inverters of I1 and I2 with same length and but larger channel width to achieve less resistance for the desired LV 1.2V Vdd operation. The details of operation between the paired Flash strings and each corresponding SRAM cell will be explained in accordance with the preferred set of bias conditions shown in FIG. 3b and the timeline control shown in FIG. 3c below.

The definitions of signal names shown in FIG. 3b and FIG. 3c and further in other memory cell diagrams are explained below.

a) BL: Bit line

### b) BLB: Complementary BL

c) Q and QB: The paired input and output nodes of each 6T SRAM cell
d) SWL: SRAM's word line
e) SFwrite: Bridge connection control for writing each SRAM data directly into each Flash's string with the reversed data
f) FSwrite: The reversed Bridge connection control for writing each Flash period data into each SRAM's Q and QB with a correct data polarity
g) SG1: Top Select transistor gate's control signal of a 3T 2-poly FString
h) SG2: Bottom Select transistor gate's control signal of a 3T 2-poly FString
i) FWL: 2-poly Flash cell's gate word line control
j) FSL: 2-poly Flash string's source line.

There are several major differences of the preferred bias conditions shown in the table of FIG. 3b comparing to prior art tables of FIG. 2d and FIG. 1e. Specifically, a first difference is that two extra LV signals of SFwrite and FSwrite per one Bridge circuit are required in the preferred bias conditions based on the improved SRAM cell according an embodiment of the present invention. In an embodiment, the voltages of SFwrite and FSwrite swing between Vdd and Vss. The advantage is that no HV device is required during the above said two writing operations.

A second difference is that a two-routes connection is provided for each top paired nodes of each paired flash strings to the paired Q and QB nodes of each SRAM cell through two opposite Bridge connections between the SRAM cell and the Flash cell. As shown in FIG. 3a, two LV NMOS transistors M3 and M5 are commonly gated by the FSwrite control line and two other LV NMOS transistors M4 and M6 are commonly gated by a SFwrite control line. An alternative pair of LV NMOS transistors, M3 and M4, has a first common drain node connected to the Q node of the SRAM cell. The other pair of LV NMOS transistors, M4 and M5, has a first common source node connected to the drain terminal of the FString1 of the Flash cell. Additionally, an alternative pair of LV NMOS transistors, M5 and M6, has a second common drain node connected to the QB node of the SRAM cell. The other pair of LV NMOS transistors, M3 and M6, has a second common source node connected to the drain terminal of the FString2 of the Flash cell. It is distinct from the prior art where only an one-route connection between the paired Flash strings and SRAM cell exists.

Further, only one of SFwrite and FSwrite is turned on at a time for two independent NVSRAM operations. In other words, the logic of SFwrite and FSwrite control lines is complementary during the data writing between the SRAM cell and Flash cell. But during normal SRAM operation, the Bridge circuit is disabled to make Flash cell in high impedance state compared to SRAM cell.

Furthermore, It is known that in the prior art for two NVSRAM writing operations, the Flash string source line FSL uses Vdd voltage to allow a current flow from the Flash string that stores Vₜ0 to charge the Q or QB node of the SRAM cell to set the SRAM cell data. Here in the present invention, instead of charging up Q or QB node, FSL is preferably held at Vss level upon the power-up cycle, the Q or QB node will be discharged to the Vss level through the Flash string that stores Vₜ0 to set data to the Q or QB node of the SRAM cell. Q or QB is associated with a “1” state if it is set to Vdd, otherwise is associated with a “0” state if it is set to Vss. This is especially applicable for 1.2V Vdd operation.

Referring to FIG. 3b, 2-poly NVSRAM operations of the present invention are illustrated and explained in detail below. First of all, a Flash Erase operation is executed using FN-channel Erase scheme. The Flash Erase operation is unrelated to SRAM cell. During each Flash cell's Erase operation, each SRAM cell's paired nodes of Q and QB have to be isolated from the Flash cell by grounding both SFwrite and FSwrite control signals. The Erase bias conditions and the preferable targeted specs are summarized as: a) Flash gate voltage, FWL is set to be <−12V; b) Flash Bulk voltage=Flash Source voltage=P-sub=0V; c) Erase time: ≦10 ms for density ≧200 Mb; d) Erase verification: No need by using one long pulse; e) Erased value Vₜ=Vₜ0≦−2V. After the Erase operation, the Vₜ levels of two 2-poly flash transistors, MC1 and MC2, in two Flash strings would become an identical value of Vₜ0≦−2V.

Secondly, a Flash Program-Inhibit operation of the 2-poly NVSRAM cell also is executed using FN-channel scheme. The Program biased conditions and the preferable targeted specs are summarized as: a) Flash gate voltage, FWL ≦+12V; b) Flash drain voltage=Flash source voltage ≧5V with Psub=0V; c) Flash cell's Vₜ level stays with Vₜ0 without change after the Program operation.

Next, a SRAM normal Read operation is illustrated. In an embodiment, the Flash cell has to be isolated from the SRAM cell by grounding the top select gate, SG1. Other Flash control signals are in “X” state, where “X” means “don't-care.” In the embodiment, SWL has to be turned on by setting to Vdd when the SRAM cell is selected.

Additionally, a Writing Flash from SRAM operation is described below. In this operation, one paired flash cells in the paired Flash strings and one SRAM cell are involved. In a specific embodiment, only one HV signal of +12V is applied to the flash word line FWL. Bridge connection control signal SFwrite is held at Vdd to turn on Bridge transistors MC4 and MC6 to allow SRAM cell's paired Q and QB nodes to have a direct route connection to the paired flash cells MC1 and MC2 in the paired Flash strings (FString1 and FString2). Reversed Bridge connection control signal FSwrite is coupled to the ground Vss level to prevent the reversed route connection between the paired QB and Q nodes of SRAM cell to the paired flash cells MC1 and MC2. Within the one paired flash bits, only one flash bit is programmed to Vₜ1 level from initial erased value of Vₜ0 and the other complementary flash bit get program inhibited to keep it at the erased Vₜ0 value (≦−2V). The flash cell in the Flash string with Vdd applied to the drain terminal gets program inhibited, while the flash cell in the Flash string with Vss applied to the drain terminal get the programmed. After the Program operation, the Flash cell stored data (in the paired flash bits) is just opposite to Q and QB. For instance, if Q is “1” at Vdd level, then MC1 gets program inhibited to keep its Vₜ0 value unchanged, which is associated with a “0” state. On the contrary, QB is “0” at Vss level, then MC2 gets programmed and its Vₜ level becomes Vₜ1 level, which is associated with a “1” state.

The reason that MC1 gets program inhibited is because the Program scheme uses the Self-Boosting Program-Inhibit (SBPI) method. When the FWL control signal is ramped to +12V, channel bias level of the flash transistor MC1 would be coupled to above 5V, which will reduce the effective electrical field between its gate and the channel. As a result, FN-tunneling effect is not induced in this floating-gate flash transistor. Thus the Vₜ level of the flash transistor MC1 is not altered and stays with its initial Vₜ value, which is Vₜ0 (≦−2V) of an erased state. Conversely, when FWL control signal is ramped to +12V, channel bias level of the flash transistor MC2 is directly connected to the ground level Vss as both its drain and source are coupled to the Vss. As a high-coupling ratio of MC2 cell, the FN tunneling effect will be induced in the tunneling oxide of floating-gate flash transistor MC2. As a result, the Vₜ level od the flash transistor MC2 will be increased from initial Vₜ0 level to Vₜ1 (≧+2V). Therefore, a conclusion is: The Program operation of a NVSRAM cell of the present invention just needs one HV signal of +12V applied to the FWL control line which is much lower than a value of +18V or higher in prior art. The rest control signals are either set to Vdd or Vss. Thus, it is much easier to be executed for the NVSRAM cell operated at 1.2V Vdd power supply because smaller on-chip charge pump can be used to generate the required a reduced HV signal of +12V within 5 ms for an In-system programmable NVSRAM cell.

Further, a Writing SRAM from Flash operation is described. In this operation, one paired flash cells, MC1 and MC2, in the paired Flash strings and one SRAM cell are involved. In a specific embodiment, No HV signal is required and FWL is coupled to Vdd with FSL is Vss. Reversed Bridge connection control signal FSwrite is held at Vdd to turn on both Bridge transistors M3 and M5 for enacting the reversed route connection between the SRAM cell's paired QB and Q nodes to the paired flash cells MC1 and MC2 in the paired Flash strings. At the same time, Bridge connection control signal SFwrite is coupled to the ground level to prevent the direct route connection between the paired Q and QB nodes of SRAM cell to the paired flash cells MC1 and MC2. Within the paired flash bits MC1 and MC2, only one flash bit stored with the Vₜ0 level will conduct a current from Q or QB node to the FSL which is held at the Vss level. While the complementary flash bit stored with the Vₜ1 level will not conduct a current when the FWL is coupled to at Vdd. For instance, if the flash transistor MC1 stores a Vₜ0 level and correspondingly QB stores Vdd, the current will flow from QB node through the Bridge transistor M5, top Select transistor ST1, flash transistor MC1 and bottom Select transistor ST2, all gated to Vdd level, to the FSL held at the Vss level. In an embodiment, the ratio of I1 Inverter's PMOS resistance has to be lower than the total pull-down resistance of M5, ST1, MC1 and ST2. As a result, the QB node will be reset to Vss level to have same polarity of stored data of the flash transistor MC1.

In the prior art, since there is no Bridge circuit between the SRAM cell and the Flash cell to provide a reverse route connection, in order to set QB node to Vss, it has to set Q node to Vdd first. Further, in order to set Q node to Vdd, the FSL control signal has to be set to Vdd. Then the current flow (upward) is from FSL to Q node through the bottom Select transistor ST2, the flash transistor MC1 and the top Select transistor ST1 as shown in FIG. 1c. Although FSL control voltage is set to Vdd, the voltage value at Q node becomes Vdd−Vₜs, where Vₜs is threshold voltage of ST1 and ST2. The voltage value of Vdd−Vₜs at Q node has to be larger than the Vₜ value of I1 Inverter of SRAM cell for writing data into the SRAM cell. When the power supply voltage Vdd is 1.8V, Vdd−Vₜs may still be larger than Vₜ value of I1 Inverter of SRAM cell so that it has certain room to set the QB node to Vss, then the Q node becomes Vdd. But when the SRAM comes to an 1.2V Vdd operation, the value of Vdd−Vₜs is only around 0.5-0.6V in the worst-case situation which is not large enough to induce cell writing of SRAM. As a result, the QB node cannot be set to the Vss, thus Q node cannot be set to Vdd. In other word, the Flash data writing into SRAM cell will fail.

Therefore, the conclusion about the Write from SRAM to Flash operation is that in order to write the same polarity data from each Flash cell into each SRAM cell of each NVSRAM at 1.2V Vdd operation, a preferred charge pull-down instead of a charge pull-up on Q or QB nodes of SRAM cell is justified of this invention for the NVSRAM cell operated at 1.2V Vdd.

Furthermore, a SRAM normal Read and Write operation is described. In a specific embodiment, each SRAM normal operation has to be not affected by each Flash part of each NVSRAM cell, regardless of Read and Write operation. In order to achieve that, both SFwrite and FSwrite control signals have to be grounded to completely isolate each Flash cell from each SARM cell. The rest of control signals of SG1, FWL, SG2 and FSL can be held at Vss. In order to make this 2-poly NVSRAM's SRAM fully compatible with traditional SRAM, the junction of Q- and QB-connected Flash path has to be made with a capacitance as small as possible. Since the SRAM cell has two PMOS devices that are formed within N-well, the silicon area is much bigger than the rest of NMOS transistors of two Invertors I1 and I2, the Bridge circuit, and two Flash strings, FString1 and FString2. As a result, the total area of overhead of the NVSRAM cell of the present invention is not high.

Referring to FIG. 3b again, it shows a table that contains one set of detailed bias conditions of above said key operations. Each operation is designed to be totally independent from the other operation. Only FWL has four voltages levels such as Vpp (e.g., +12V), Vdd, Vss, and Vnn (e.g., −12V). The rest of the signals only have two voltages levels of Vdd and Vss. Since only FWL requires Vpp of +12V or lower during the FN-tunneling channel Program operation, the charge time is quick because no P/N junction is involved. Thus an easier circuit control and smaller HV charge pump can be built in on-chip configuration for a fast Program operation within 10 ms for NVSRAM cell density as high as 200M bits.

FIG. 3c shows the preferred timelines for each operation of the 16T 2-poly NVSRAM cell of the present invention. This diagram is merely an example, which should not unduly limit the scope of the claims herein. One of ordinary skill in the art would recognize other variations, modifications, and alternatives. Although the timeline shows t1, t2, t3, t4 and t5 in X-axis, it is not intended to show a timing sequence. It just shows each operation with a preferred bias condition for the related control signals of the SRAM cell, the Bridge circuit, and a paired 3T Flash strings of FIG. 3a according to an embodiment of the present invention. From 0 to t1 period, the NVSRAM cell is presumed to be in an Initial state where Q and QB nodes of the SRAM cell are respectively biased at Vdd and Vss while the word line SWL is set to Vss along with all control lines for the Flash cell and Bridge circuit.

In a period of t1 to t2, it shows a bias conditions for all the control lines during a Flash Erase state. The SRAM cell is isolated from the Flash cell with both SFwrite and FSwrite control lines being set to Vss to shut down the connection. The top Select transistor gate line SG1 s grounded to isolate the HV signal from the flash transistor from affecting the SRAM cell. The bottom Select transistor gate line SG2 is set to Vdd to turn on that transistors of ST2 and ST4 to allow Vss connected to the source nodes of MC1 and MC2 flash cells for simultaneous erase operation in accordance with the bias conditions shown in FIG. 3b. The Flash word line FWL is applied to Vnn=−12V to induce a FN tunneling effect to erase the Flash bit.

In a period of t2 to t3, it demonstrates a Flash Program/Program-Inhibit State during which the SRAM cell data, Q at Vdd and QB at Vss, is written into one of the flash transistor of the two 3T Flash strings. This state usually is triggered by a power-off moment. Correspondingly, SFwrite line is set to Vdd to open a direct route from the paired nodes of Q and QB to the paired Flash strings. SG1 is set to Vdd to open the gates of two top Select transistors ST1 and ST3 and SG2 is set to Vss to close the gates of two bottom Select transistors ST2 and ST4 for preventing charge leak to the flash source line FSL. Flash word line FWL is applied Vpp=+12V to induce FN tunneling effect in one string with QB drain node at Vss to write SRAM cell data to the flash cell, MC1, in corresponding Flash string while not inducing a FN tunneling in the other Flash string with Q drain node at Vdd to cause the corresponding flash cell, MC2, to be program-inhibited.

In another period of t3 to t4, a Flash Load into SRAM state is shown. This state is usually triggered by a power-up moment. SFwrite and FSwrite control lines are switched their setting at Vss and Vdd level to open a reverse route connection between the paired Flash bits and the paired nodes of QB and Q of the SRAM cell. All SG1, SG2, and FWL lines are set to Vdd, but only to allow a current flow only one Flash string with one flash bit stored with the Vₜ0 level from the Q or QB node to the FSL which is held at the Vss level. While the complementary flash bit stored with the Vₜ1 level will not conduct a current. The reversed route ensure the polarity of original SRAM data is correctly written back to correspond Q and QB node of the SRAM cell.

In yet another period of t4 to t5 showing bias conditions for a SRAM Read state. During the period, SRAM word line SWL is applied to Vdd to open the latch of SRAM and both SFwrite and FSwrite control signals are all coupled to ground level for isolating the SRAM cell from the Flash cell. All other control lines of the Flash cell is grounded.

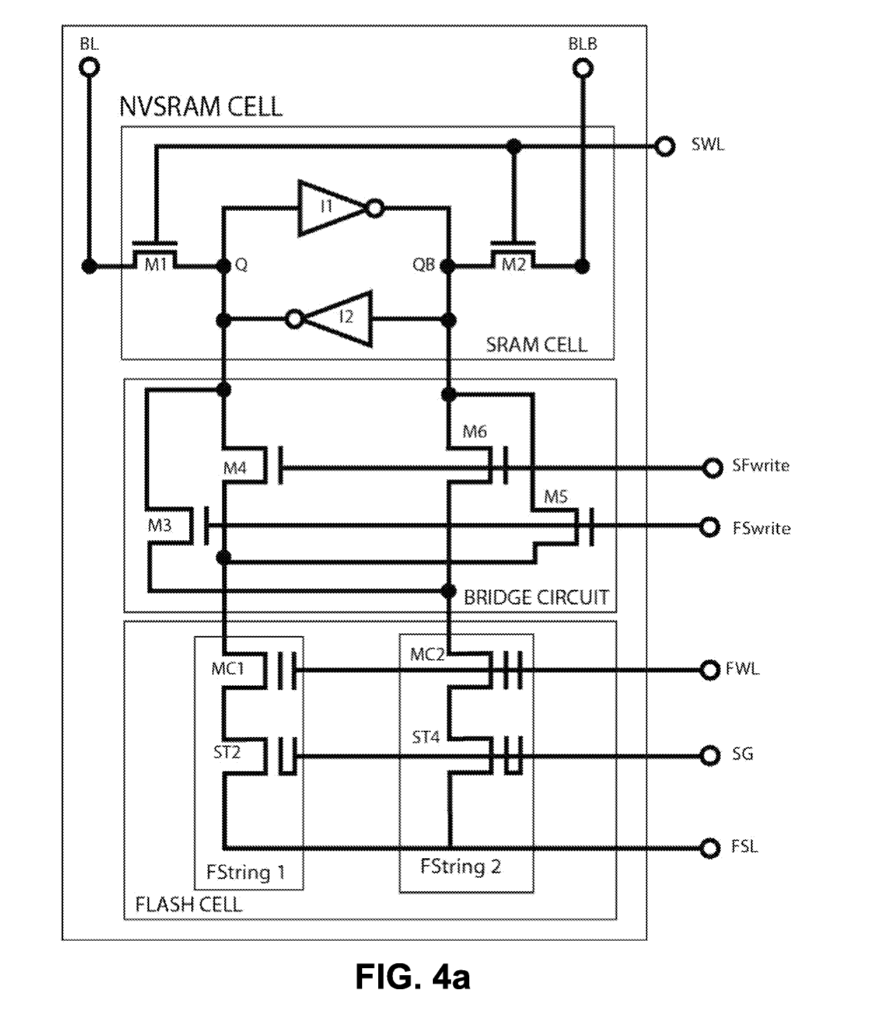

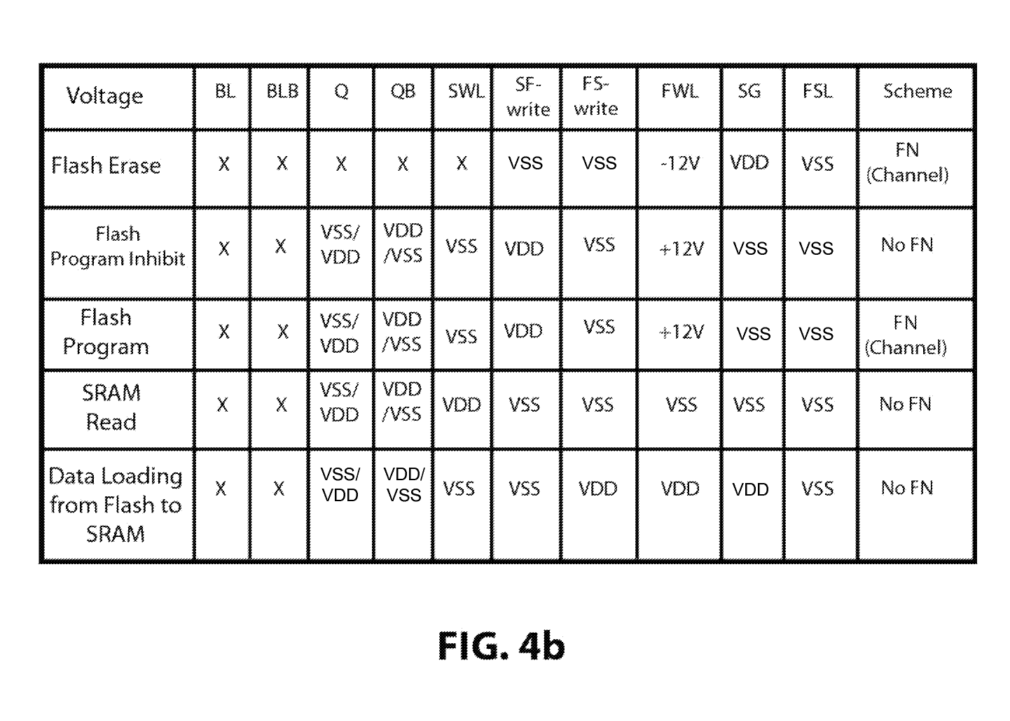

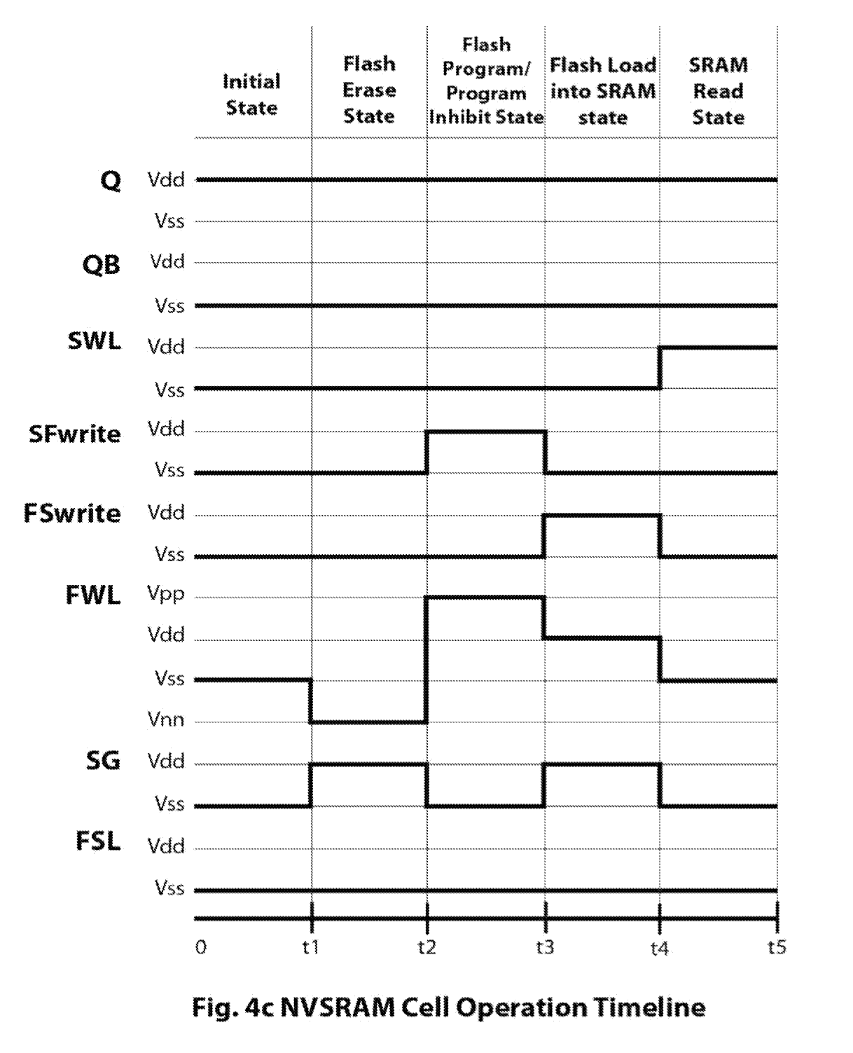

FIG. 4a shows the second embodiment of the present invention of a 14T 2-poly NVSRAM cell according to another embodiment of the present invention. This diagram is merely an example, which should not unduly limit the scope of the claims herein. One of ordinary skill in the art would recognize other variations, modifications, and alternatives. As shown, FIG. 4a is substantially similar to the 16T NVSRAM cell diagram shown in FIG. 3a with a top SRAM cell, a bottom two Flash strings and a Bridge circuit in the middle. But each of the Flash string comprises only two transistors including one 2-poly floating-gate NMOS flash transistor MC1 and a bottom 1-poly NMOS Select transistor ST2 for the FString1 and similar two transistors MC2 and ST4 for the FString2. The ST1 and ST3 appeared in FIG. 3a have been removed from FString1 and FString2 respectively. In this embodiment, there is one advantage to reduce the number of transistors in each FString although two penalties may be involved. A first penalty is that all Bridge circuit transistors M3, M4, M5 and M6 have to be changed to a HV NMOS transistor like the ST2 and ST4 originally used as the top Select transistor in the Flash strings. This is intended to sustain a high voltage Vds of 7V or higher across drain-source during the SBPI operation. While in the 16T NVSRAM cell shown in FIG. 3a, all bridge transistors of M3, M4, M5 and M6 can be made with LV devices same as the SRAM cell's LV NMOS transistor in Inverters of I1 and I2. A second penalty is the risk of failure of SBPI scheme for the flash transistor MC1 and MC2 during the FN channel Program operation. Therefore, MC1 and MC2 flash transistors have to be made with a larger gate area to increase the coupling charges from gates to channels to ensure the success of the Program-Inhibit operation. Note, increasing flash transistor gate area has one disadvantage to cause the flash cell size larger. Secondly, increasing gate area is to increase the coupling charges to channel but not to increase the coupling ratio from gate to channel. However, since two Select transistors are removed comparing to the 16T NVSRAM cell, the 14T NVSRAM cell can offer certain silicon area as required for a larger Flash cell size without increasing the NVSRAM cell size.

FIG. 4b show a table that contains one set of detailed bias conditions of above said key operations of FIG. 4a. As described before, this 2-poly NVSRAM cell has only one paired bottom Select transistors sharing a common gate control line SG perpendicular to the two Flash strings. Therefore signal control line SG1 in FIG. 3a has been deleted and gate control line SG2 has been changed to SG. The rest of signals biased conditions remain the same as the table shown in FIG. 3b.

Again, each NVSRAM operation is designed to be totally independent from the other operation. Only FWL control signal has four voltages levels such as Vpp, Vdd, Vss and Vnn. The rest of signals have only two voltages levels of Vdd and Vss. Since only FWL control signal requires Vpp of about +12V during the FN channel program operation, the charge time is quick because no P/N junction is involved. Thus an easier circuit control and smaller HV charge pump can be built in an on-chip configuration for a fast program operation within 10 ms for NVSRAM cell density as high as 200M bits.

FIG. 4c shows the preferred timelines for each operation of the 14T 2-poly NVSRAM cell according to an alternative embodiment of the present invention. As described before, this 14T 2-poly NVSRAM cell has only one paired bottom Select transistors sharing a common gate control line SG perpendicular to the two Flash strings. The timeline has removed gate control line SG1 and replaces SG2 by SG as explained above. Although the time shows t1, t2, t3, t4 and t5 in X-axis, it is not intended to show the timing sequence. It just shows each operation with a preferred bias condition for the related control signals of the SRAM cell, the Bridge circuit, and a paired 2T Flash strings of FIG. 4a according to an alternative embodiment of the present invention. Since the details have been explained previously for the embodiment of 16T NVSRAM cell with two 3T Flash strings, the description for current embodiment of 14T NVSRAM cell with two 2T Flash strings is substantially similar and will be skipped for here.

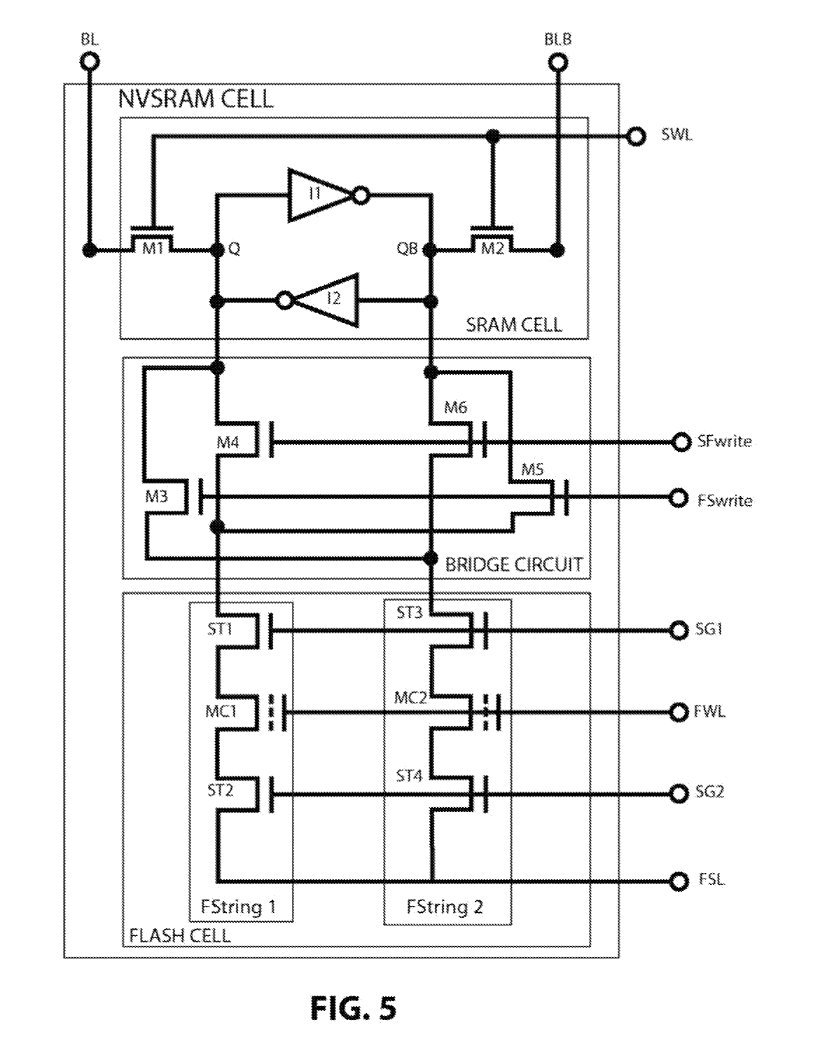

FIG. 5 is another embodiment of a 16T NVSRAM cell comprising an 1-poly charge-trapping type SONOS or MONOS flash transistor in each of the two 3T Flash strings of a Flash cell according to the present invention. As shown, the cell circuit is substantially the same configuration as that in FIG. 3a except that the single-poly charge-trapping type SONOS or MONOS Flash strings replaces the 2-poly floating-gate Flash strings. An advantage of this flash-cell type is that for Program and Erase operations of the 16T NVSRAM cell the word line of the Flash cell (FWL) can use much lower gate voltages of +7V and −7V respectively. They are much lower than ones used in the 2-poly floating-gate type flash transistor as shown in FIG. 3a. Correspondingly the bias conditions for all the control lines are the same as that shown in FIG. 3b except the FWL signal is reduced.

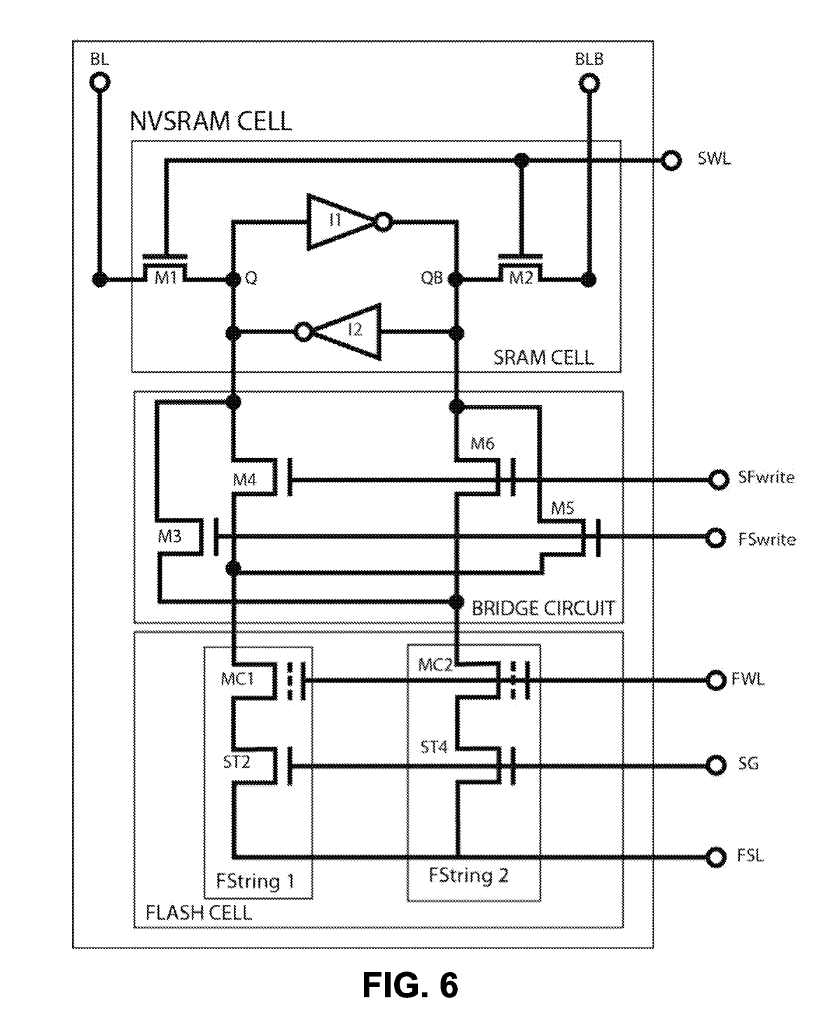

FIG. 6 is yet another embodiment of a 14T NVSRAM cell comprising an 1-poly charge-trapping type SONOS or MONOS flash transistor in each of the two 2T Flash strings of a Flash cell according to the present invention. As shown, the cell circuit is substantially the same configuration as that in FIG. 4a except that the single-poly charge-trapping type SONOS or MONOS Flash strings replaces the 2-poly floating-gate Flash strings. Correspondingly the bias conditions for all the control lines are the same as that shown in FIG. 4b except the FWL signal is reduced. All key 14T NVSRAM operations should be similar to previous embodiments shown in FIG. 4b and FIG. 4c.

In a specific embodiment, the present invention provides a 16T NVSRAM memory cell circuit with low-voltage fast-write scheme. The 16T NVSRAM memory cell includes a SRAM cell, a Flash cell, and a Bridge circuit coupling between the SRAM cell and the Flash cell. The SRAM cell is substantially illustrated in the top portion of the FIG. 3a or FIG. 5. The SRAM cell includes a first access transistor M1 and a second access transistor M2 sharing a first word line SWL and respectively coupling between a first bit line BL and a first data node Q and between a second bit line BLB and a second data node QB. The first data node Q and the second data node QB respectively are coupled to two cross-coupled invertors I1 and I2 made by four LV CMOS transistors.

The Flash cell is substantially illustrated in the bottom portion of the FIG. 3a and FIG. 5. The Flash cell includes a first cell string FString1 and a second cell string FString2 sharing a common P-sub. FString1/FString2 includes a first/second top Select transistor ST1/ST3, a first/second Flash transistor MC1/MC2, and a first/second bottom Select transistor ST2/ST4 connected in series. In a specific embodiment, the first/second Flash transistor is a 2-poly floating-gate type NMOS transistor. In another specific embodiment, the first/second Flash transistor is an1-poly charge-trapping type SONOS or MONOS transistor. Each Select transistor ST1, ST2, ST3, or ST4 is a HV NMOS transistor capable of protecting the high-voltage Vds of 7V and above across drain and source of the Flash transistor from affecting the SRAM cell. The first and the second top Select transistors ST1 and ST3 are gated commonly by a first select-gate control line SG1 and respectively associated with a first drain terminal and a second drain terminal. The first and the second bottom Select transistors ST2 and ST4 are gated commonly by a second select-gate control line SG2 and respectively associated with a first source terminal and a second source terminal. The first and the second Flash transistors MC1 and MC2 are gated commonly by a second word line FWL. The first source terminal and the second source terminal are connected together to a flash source line FSL.

The Bridge circuit is substantially illustrated in the middle portion of the FIG. 3a and FIG. 5. The Bridge circuit includes a first, second, third, and fourth LV NMOS transistor M3, M4, M5, and M6 for connecting the first data node Q and the second data node QB of the SRAM cell respectively through two cross routes to the first drain terminal and the second drain terminal of the Flash cell. The first and the third LV NMOS transistors M3 and M5 are commonly gated by a FSwrite control line and the second and the fourth LV NMOS transistors M4 and M6 are commonly gated by a SFwrite control line. The first and the second LV NMOS transistors M3 and M4 have a first common drain node connected to the first data node Q of the SRAM cell. The second and the third LV NMOS transistors M4 and M5 have a first common source node connected to the first drain terminal of the Flash cell. The third and the fourth LV NMOS transistors M5 and M6 have a second common drain node connected to the second data node QB of the SRAM cell. The first and the fourth LV NMOS transistors M3 and M6 have a second common source node connected to the second drain terminal of the Flash cell.

In a specific embodiment, only one of the FSwrite control line and the SFwrite control line is turned on at a time by coupling to a power supply voltage as low as 1.2 V Vdd. This operation scheme provides a direct route of writing data from the SRAM cell to the Flash cell via a FN tunneling effect by setting only one HV of +12V or lower to the second word line and provides an alternate route of loading data from the Flash cell to the SRAM cell by conducting current from the first or second data node to a grounded flash source line. The same operation scheme ensures a reversed polarity of each data from the Flash cell can be reversely loaded into the SRAM cell operating at the power supply voltage as low as 1.2 V Vdd.

In an alternative embodiment, the present invention provides a 14T NVSRAM memory cell circuit with low-voltage fast-write scheme. The 14T NVSRAM memory cell includes a SRAM cell, a Flash cell, and a Bridge circuit coupling between the SRAM cell and the Flash cell. In particular, the SRAM cell is a circuit depicted at the top portion of FIG. 4a and FIG. 6. The SRAM cell includes a first access transistor M1 and a second access transistor M2 sharing a first word line SWL and respectively coupling between a first bit line BL and a first data node Q and between a second bit line BLB and a second data node QB. The first data node Q and the second data node QB respectively are coupled to two cross-coupled invertors I1 and I2 made by four LV CMOS transistors. The SRAM cell is configured to be operated at low power supply voltage Vdd as low as 1.2 V. The first data node Q and the second data node QB either store Vdd for a “1” state or store Vss (ground voltage) for a “0” state.

The Flash cell is substantially depicted in the bottom portion of FIG. 4a and FIG. 6, including a first cell string FString1 and a second cell string FString2 sharing a common P-sub. the first/second cell string FString1/FString2 includes at least a first/second Flash transistor MC1/MC2 connected in series to a first/second Select transistor ST2/ST4. In a specific embodiment, the first/second Flash transistor is a 2-poly floating-gate type NMOS transistor. In another specific embodiment, the first/second Flash transistor is an1-poly charge-trapping type SONOS or MONOS transistor. Each Select transistor ST2 or ST4 is a HV NMOS transistor capable of protecting the high-voltage Vds of 7V and above across drain and source of the Flash transistor from affecting the SRAM cell. The first and the second Select transistors are gated commonly by a select-gate control line and respectively associated with a first source terminal and a second source terminal. The first and the second Flash transistors are gated commonly by a second word line. The first source terminal and the second source terminal are connected together to a flash source line.

The Bridge circuit is substantially one depicted in the middle portion of FIG. 4a and FIG. 6 including a first, second, third, and fourth HV NMOS transistor (M3 through M6) for connecting the first data node Q and the second data node QB of the SRAM cell respectively through two cross routes to the first drain terminal and the second drain terminal of the Flash cell. The first and the third HV NMOS transistors M3 and M5 are commonly gated by a FSwrite control line and the second and the fourth HV NMOS transistors are commonly gated by a SFwrite control line. The first and the second HV NMOS transistors M3 and M4 have a first common drain node connected to the first data node Q of the SRAM cell. The second and the third HV NMOS transistors M4 and M5 have a first common source node connected to the first drain terminal of the Flash cell. The third and the fourth HV NMOS transistors M5 and M6 have a second common drain node connected to the second data node QB of the SRAM cell. The first and the fourth HV NMOS transistors M3 and M6 have a second common source node connected to the second drain terminal of the Flash cell.

In a specific embodiment, only one of the FSwrite control line and the SFwrite control line is turned on at a time by coupling to a power supply voltage as low as 1.2 V Vdd. This operation scheme provides a direct route of writing data from the SRAM cell to the Flash cell via a FN tunneling effect by setting only a HV of +12V to the second word line when the Flash transistor uses 2-poly floating-gate type NMOS transistor or an even lower voltage of +7V to the second word line when the Flash transistor uses 1-poly charge-trapping type SONOS or MONOS transistor. Further, this operation scheme provides an alternate route of loading data from the Flash cell to the SRAM cell by conducting current from the first or second data node to a grounded flash source line. The same operation scheme ensures a reversed polarity of each data from the Flash cell can be reversely loaded into the SRAM cell operating at the power supply voltage as low as 1.2 V Vdd.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A 16T NVSRAM memory cell circuit with low-voltage fast-write scheme, the 16T NVSRAM memory cell comprising:
a SRAM cell comprising a first access transistor and a second access transistor sharing a first word line and respectively coupling between a first bit line and a first data node and between a second bit line and a second data node, the first data node and the second data node respectively being coupled to two cross-coupled invertors made by four LV CMOS transistors;
a Flash cell comprising a first cell string and a second cell string sharing a common P-sub, the first/second cell string including a first/second top Select transistor, a first/second Flash transistor, and a first/second bottom Select transistor connected in series, the first and the second top Select transistors being gated commonly by a first select-gate control line and respectively associated with a first drain terminal and a second drain terminal, the first and the second bottom Select transistors being gated commonly by a second select-gate control line and respectively associated with a first source terminal and a second source terminal, the first and the second Flash transistors being gated commonly by a second word line, the first source terminal and the second source terminal being connected together to a flash source line; and
a Bridge circuit including a first, second, third, and fourth LV NMOS transistor for connecting the first data node and the second data node of the SRAM cell respectively through two cross routes to the first drain terminal and the second drain terminal of the Flash cell, wherein the first and the third LV NMOS transistors are commonly gated by a FSwrite control line and the second and the fourth LV NMOS transistors are commonly gated by a SFwrite control line; wherein the first and the second LV NMOS transistors have a first common drain node connected to the first data node of the SRAM cell; the second and the third LV NMOS transistors have a first common source node connected to the first drain terminal of the Flash cell; wherein the third and the fourth LV NMOS transistors have a second common drain node connected to the second data node of the SRAM cell; the first and the fourth LV NMOS transistors have a second common source node connected to the second drain terminal of the Flash cell;
wherein only one of the FSwrite control line and the SFwrite control line is turned on at a time by coupling to a power supply voltage as low as 1.2 V Vdd for providing a direct route of writing data from the SRAM cell to the Flash cell via a FN tunneling effect by setting only one HV of +12V or lower the second word line and providing an alternate route of loading data from the Flash cell to the SRAM cell by conducting current from the first or second data node to a grounded flash source line so that a reversed polarity of each data from the Flash cell can be reversely loaded into the SRAM cell operating at the power supply voltage as low as 1.2 V Vdd.

2. The 16T NVSRAM memory cell of claim 1 wherein each of the first and second top/bottom Select transistors is an 1-poly HV NMOS transistor formed by shorting a Poly2 control gate to a Poly1 floating gate of a 2-poly HV NMOS floating-gate transistor.

3. The 16T NVSRAM memory cell of claim 1 wherein each of the first and second Flash transistors is a 2-poly floating-gate type NMOS transistor.

4. The 16T NVSRAM memory cell of claim 1 wherein each of the first and second Flash transistors is an1-poly charge-trapping type SONOS or MONOS transistor.

5. The 16T NVSRAM memory cell of claim 3 wherein the Flash cell is subjected to an erase operation by setting the second word line to a negative voltage no greater than −12V to achieve a FN-tunneling effect on each 2-poly floating-gate type NMOS transistor with respect to 0 V applied to the first select-gate control line, the flash source line, and the common P-sub and the Vdd level applied to the second select-gate control line.

6. The 16T NVSRAM memory cell of claim 4 wherein the Flash cell is subjected to an erase operation by setting the second word line to a negative voltage no greater than −7V to achieve a FN-tunneling effect on each 1-poly charge-trapping type SONOS or MONOS transistor with respect to 0 V applied to the first select-gate control line, the flash source line, and the common P-sub and the Vdd level applied to the second select-gate control line.

7. The 16T NVSRAM memory cell of claim 1 wherein the Flash cell is erased via FN-tunneling effect to bring a threshold voltage level of each of the first Flash transistor and the second Flash transistor to a Vₜ0 level of −2V or smaller within 10 ms for cell density greater than 200 Mb.

8. The 16T NVSRAM memory cell of claim 1 wherein the Flash cell is erased independent to the SRAM cell wherein each of the first data node and the second data node is isolated from the Flash cell by grounding both the FSwrite control line and the SFwrite control line.

9. The 16T NVSRAM memory cell of claim 1 wherein the Flash cell is subjected to a Writing operation from the SRAM cell having the first data node at Vss=0V level and the second data node at the Vdd level to cause the first Flash transistor being subjected to a program operation to increase its threshold voltage level from a Vₜ0 level of no greater than −2V to a Vₜ1 level of greater than +2V and the second Flash transistor being subjected to a program-inhibit operation to retain its threshold voltage level at the Vₜ0 level.

10. The 16T NVSRAM memory cell of claim 9 wherein the Writing operation from the SRAM cell is associated with following control bias conditions including setting the Vss to the first word line, setting +12V or lower to the second word line connect a gate of a 2-poly floating-gate NMOS transistor of the first Flash transistor, setting the Vdd to the SFwrite control line to open a direct route from the first data node through the second LV NMOS transistor to the first Flash transistor and from the second data node through the fourth LV NMOS transistor to the second Flash transistor, setting the Vss to the FSwrite control line, setting the Vdd to the first select-gate control line, setting the Vss to the second select-gate control line, and keeping the flash source line and the common P-sub to the Vss.

11. The 16T NVSRAM memory cell of claim 9 wherein the first Flash transistor is programmed within 10 ms for cell density greater than 200 Mb.

12. The 16T NVSRAM memory cell of claim 9 wherein the second Flash transistor subjecting to the program-inhibit operation by coupling a channel voltage of greater than 5 V for the corresponding 2-poly floating-gate type NMOS transistor to not induce a FN tunneling effect when the second word line is set to +12V and its drain node being coupled to the Vdd level from the second data node as the SFwrite control line and the first select-gate control line are set to the Vdd level.

13. The 16T NVSRAM memory cell of claim 1 wherein the SRAM cell is subjected to a read operation by setting the first word line to the Vdd level, the read operation being isolated from the Flash cell by setting the SFwrite control line, the FSwrite control line, and the first select-gate control line to the Vss level.

14. The 16T NVSRAM memory cell of claim 1 wherein the SRAM cell is subjected to a Writing operation from the Flash cell having the first Flash transistor at a threshold voltage level of Vₜ1 of greater than +2V and the second Flash transistor at a threshold voltage level of Vₜ0 of smaller than −2V to cause the first data node to be reset to the Vss level and the second data node correspondingly to be reset to the Vdd level.

15. The 16T NVSRAM memory cell of claim 14 wherein the Writing operation from the Flash cell is a associated with following control bias conditions including setting the Vss to the first word line, setting the Vdd to the second word line, setting the Vss to the SFwrite control line, setting the Vdd to the FSwrite control line to open a reverse route from the second Flash transistor through the first LV NMOS transistor to the first data node and from the first Flash transistor through the third LV NMOS transistor to the second data node, setting the Vdd to the first select-gate control line and the second select-gate control line, and keeping the flash source line and the common P-sub to the Vss.

16. The 16T NVSRAM memory cell of claim 14 wherein the second Flash transistor at the Vₜ0 of smaller than −2V causes a current flow from the first data node at the Vdd level through the first LV NMOS transistor, the second top Select transistor, the second Flash transistor, and the second bottom Select transistor, all gated by the Vdd level, to the flash source line that is grounded at the Vss to reset the first data node to the Vss level.

17. The 16T NVSRAM memory cell of claim 14 wherein the first Flash transistor at the Vₜ1 of greater than +2V blocks a current flow from the second data node through the third LV NMOS transistor to the flash source line.

18. A 14T NVSRAM memory cell circuit with low-voltage fast-write scheme, the 14T NVSRAM memory cell comprising:
a SRAM cell comprising a first access transistor and a second access transistor sharing a first word line and respectively coupling between a first bit line and a first data node and between a second bit line and a second data node, the first data node and the second data node respectively being coupled to two cross-coupled invertors made by four LV CMOS transistors;
a Flash cell comprising a first cell string and a second cell string sharing a common P-sub, the first/second cell string including at least a first/second Flash transistor connected in series to a first/second Select transistor, the first and the second Select transistors being gated commonly by a select-gate control line and respectively associated with a first source terminal and a second source terminal, the first and the second Flash transistors being gated commonly by a second word line, the first source terminal and the second source terminal being connected together to a flash source line; and
a Bridge circuit including a first, second, third, and fourth HV NMOS transistor for connecting the first data node and the second data node of the SRAM cell respectively through two cross routes to the first drain terminal and the second drain terminal of the Flash cell, wherein the first and the third HV NMOS transistors are commonly gated by a FSwrite control line and the second and the fourth HV NMOS transistors are commonly gated by a SFwrite control line; wherein the first and the second HV NMOS transistors have a first common drain node connected to the first data node of the SRAM cell; the second and the third HV NMOS transistors have a first common source node connected to the first drain terminal of the Flash cell; wherein the third and the fourth HV NMOS transistors have a second common drain node connected to the second data node of the SRAM cell; the first and the fourth HV NMOS transistors have a second common source node connected to the second drain terminal of the Flash cell;
wherein only one of the FSwrite control line and the SFwrite control line is turned on at a time by coupling to a power supply voltage as low as 1.2 V Vdd for providing a direct route of writing data from the SRAM cell to the Flash cell via a FN tunneling effect by setting only one HV of +12V or lower the second word line and providing an alternate route of loading data from the Flash cell to the SRAM cell by conducting current from the first or second data node to a grounded flash source line so that a reversed polarity of each data from the Flash cell can be reversely loaded into the SRAM cell operating at the power supply voltage as low as 1.2V Vdd.

19. The 14T NVSRAM memory cell of claim 18 wherein each of the first and second Select transistors is an 1-poly HV NMOS transistor formed by shorting a Poly2 control gate to a Poly1 floating gate of a 2-poly floating-gate NMOS transistor.

20. The 14T NVSRAM memory cell of claim 18 wherein each of the first and second Flash transistors is a 2-poly floating-gate type NMOS transistor configured to have an increased gate area for achieving increased coupling charges.

21. The 14T NVSRAM memory cell of claim 18 wherein each of the first and second Flash transistors is an1-poly charge-trapping type SONOS or MONOS transistor configured to have an increased gate area for achieving increased coupling charges.

22. The 14T NVSRAM memory cell of claim 20 wherein the Flash cell is subjected to an erase operation by setting the second word line to a negative voltage no greater than −12V to achieve a FN-tunneling effect on each 2-poly floating-gate type NMOS transistor with respect to 0 V applied to the flash source line and the common P-sub and the Vdd level applied to the select-gate control line.

23. The 14T NVSRAM memory cell of claim 21 wherein the Flash cell is subjected to an erase operation by setting the second word line to a negative voltage no greater than −7V to achieve a FN-tunneling effect on each 1-poly charge-trapping type SONOS or MONOS transistor with respect to 0 V applied to the flash source line and the common P-sub and the Vdd level applied to the select-gate control line.

24. The 14T NVSRAM memory cell of claim 18 wherein the Flash cell is erased via FN-tunneling effect to bring a threshold voltage level of each of the first Flash transistor and the second Flash transistor to a Vₜ0 level of −2V or smaller within 10 ms for NVSRAM cell density greater than 200 Mb.

25. The 14T NVSRAM memory cell of claim 18 wherein the Flash cell is erased independent to the SRAM cell wherein each of the first data node and the second data node is isolated from the Flash cell by grounding both the FSwrite control line and the SFwrite control line.

26. The 14T NVSRAM memory cell of claim 18 wherein the Flash cell is subjected to a Writing operation from the SRAM cell having the first data node at the Vdd level and the second data node at Vss=0V level to cause the second Flash transistor being subjected to a program operation to increase its threshold voltage level from a Vₜ0 level of no greater than −2V to a Vₜ1 level of greater than +2V and the first Flash transistor being subjected to a program-inhibit operation to retain its threshold voltage level at the Vₜ0 level.

27. The 14T NVSRAM memory cell of claim 26 wherein the Writing operation from the SRAM cell is associated with following control bias conditions including setting the Vss to the first word line, setting +12V or lower to the second word line connect a gate of a 2-poly floating-gate NMOS transistor of the first Flash transistor, setting the Vdd to the SFwrite control line to open a direct route from the first data node through the second HV NMOS transistor to the first Flash transistor and from the second data node through the fourth HV NMOS transistor to the second Flash transistor, setting the Vss to the FSwrite control line, setting the Vss to the select-gate control line, and keeping the flash source line and the common P-sub to the Vss.

28. The 14T NVSRAM memory cell of claim 26 wherein the first Flash transistor is programmed within 10 ms for NVSRAM cell density greater than 200 Mb.

29. The 14T NVSRAM memory cell of claim 26 wherein the first Flash transistor subjecting to the program-inhibit operation by coupling a channel voltage of greater than 5 V for the corresponding 2-poly floating-gate type NMOS transistor to not induce a FN tunneling effect when the second word line is set to +12V and its drain node being coupled to the Vdd level from the first data node as the SFwrite control line is set to the Vdd level.

30. The 14T NVSRAM memory cell of claim 18 wherein the SRAM cell is subjected to a read operation by setting the first word line to the Vdd level, the read operation being isolated from the Flash cell by at least setting the SFwrite control line and the FSwrite control line to the Vss level.

31. The 14T NVSRAM memory cell of claim 18 wherein the SRAM cell is subjected to a Writing operation from the Flash cell having the second Flash transistor at a threshold voltage level of Vₜ1 of greater than +2V and the first Flash transistor at a threshold voltage level of Vₜ0 of smaller than −2V to cause the second data node to be reset to the Vss level and the first data node correspondingly to be reset to the Vdd level.

32. The 14T NVSRAM memory cell of claim 31 wherein the Writing operation from the Flash cell is a associated with following control bias conditions including setting the Vss to the first word line, setting the Vdd to the second word line, setting the Vss to the SFwrite control line, setting the Vdd to the FSwrite control line to open a reverse route from the second Flash transistor through the first HV NMOS transistor to the first data node and from the first Flash transistor through the third HV NMOS transistor to the second data node, setting the Vdd to the select-gate control line, and keeping the flash source line and the common P-sub to the Vss.

33. The 14T NVSRAM memory cell of claim 31 wherein the first Flash transistor at the Vₜ0 of smaller than −2V causes a current flow from the second data node at the Vdd level through the third HV NMOS transistor, the first Flash transistor, and the first Select transistor, all gated by the Vdd level, to the flash source line that is grounded at the Vss to reset the first data node to the Vss level.

34. The 14T NVSRAM memory cell of claim 18 wherein the Flash cell is subjected to a Writing operation from the SRAM cell having the first data node at the Vdd level and the second data node at Vss=0V level to cause the second Flash transistor being subjected to a program operation to increase its threshold voltage level from a Vₜ0 level of no greater than −2V to a Vₜ1 level of greater than +2V and the first Flash transistor being subjected to a program-inhibit operation to retain its threshold voltage level at the Vₜ0 level.
